(19) United States
(12) Patent Application Publication
(10) Pub. No.: US 2009/0002204 A1
(43) Pub. Date: Jan. 1, 2009

(54) INFORMATION PROCESSING DEVICE AND CONTROL METHOD OF THE SAME

(75) Inventors: Tooru MAMATA, Akiruno-shi (JP); Hironori MOTOE, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA1, Tokyo (JP)

(21) Appl. No.: 12/163,842

(22) Filed: Jun. 27, 2008

(30) Foreign Application Priority Data
Jun. 29, 2007 (JP) 2007-173368

(51) Int. Cl. H03K 17/94; G06F 3/02

(52) U.S. Cl. 341/25; 345/168

(57) ABSTRACT

According to one embodiment, an information processing device includes a keyboard in which a plurality of keys are arranged, detecting unit which detects a key press of the keyboard, determining unit which determines, when the detecting unit detects two or more key presses within a predetermined period of time, whether the two or more pressed keys satisfy predetermined conditions, and invalidating unit, when the determining unit determines that the two or more pressed keys mutually satisfy the predetermined conditions, inputs made by both of the key presses.

### CROSS-REFERENCE TO RELATED APPLICATIONS

This application is based upon and claims the benefit of priority from Japanese Patent Application No. 2007-173368, filed Jun. 29, 2007, the entire contents of which are incorporated herein by reference.

### BACKGROUND

1. Field

One embodiment of the present invention the present invention relates to an information processing device such as a personal computer, and more particularly to an information processing device having a function of preventing incorrect key input, and a method of controlling the same.

2. Description of the Related Art

Generally, keys in a keyboard of a notebook type personal computer or the like are smaller than keys in a keyboard of a desktop type personal computer or the like. Furthermore, clearances between keys tend to be small. Thus, a normal key input may not be executed when two or more key inputs are erroneously performed at the same time.

In cases like the above, Jpn. Pat. Appln. KOKAI Publication No. 7-13666, for example, discloses an art in which only correct input data is transferred based on a character array pattern of a pattern memory device, when two adjacent keys are pressed with an interval shorter than a preset period of time.

According to the art disclosed in Jpn. Pat. Appln. KOKAI Publication No. 7-13666, however, a high processing capability is required for such a pattern check. Also, since an input performed within a predetermined period of time is to be verified, a key code cannot be fixed until the verification is finished. Detection of an incorrect input is accurately performed when a data pattern is correctly made. In other words, there is a problem that an incorrect input is executed if a data pattern is incorrect.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing an external view of a computer according to one embodiment of the present invention.

FIG. 2 is an exemplary block diagram showing an example of a system configuration of the computer according the present embodiment.

FIG. 3 is an exemplary block diagram showing a functional configuration of a keyboard application according to the present embodiment.

FIG. 4 is an exemplary flow chart showing a control method to which the computer according to the present embodiment is applied.

FIG. 5 is an exemplary flow chart showing a control method to which the computer according to the present embodiment is applied.

FIG. 6 is an exemplary diagram showing adjacent key map.

FIG. 7 is an exemplary diagram showing new key input map and adjacent maps of the latest keys.

FIG. 8 is an exemplary diagram showing a key arrangement of a typical keyboard.

### DETAILED DESCRIPTION

Various embodiments according to the invention will be described hereinafter with reference to the accompanying drawings. In general, according to one embodiment of the invention, an information processing device includes: a keyboard in which a plurality of keys are arranged; a detecting unit which detects a key press of the keyboard; a determining unit which determines, when the detecting unit detects two or more key presses within a predetermined period of time, whether the two or more pressed keys satisfy predetermined conditions; and a invalidating unit, when the determining unit determines that the two or more pressed keys mutually satisfy the predetermined conditions, inputs made by both of the key presses.

Now, an embodiment of the present invention will be described with reference to the accompanying drawings.

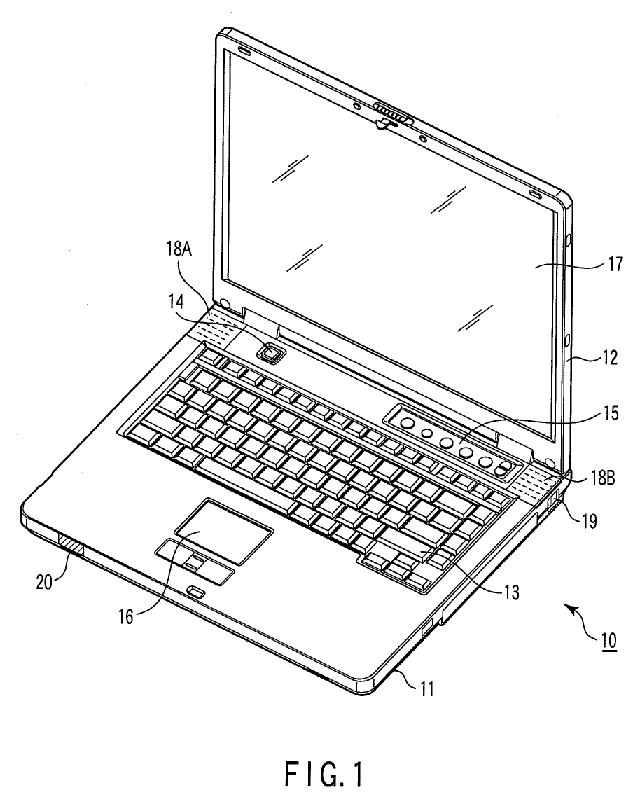

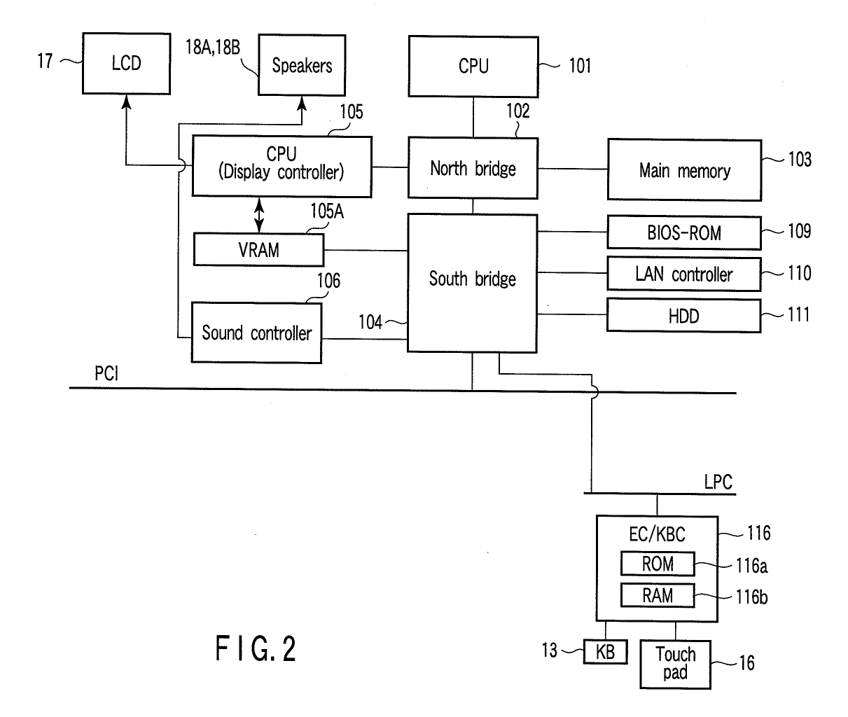

First, a configuration of an information processing device according to one embodiment of the present invention will be described with reference to FIGS. 1 and 2. This information processing device is realized as, for example, a notebook type personal computer 10.

FIG. 1 is a perspective view showing the notebook type personal computer 10 when a display unit is opened. The computer 10 comprises a computer body 11, and a display unit 12. In the display unit 12, a display device comprising a TFT-LCD (Thin Film Transistor Liquid Crystal Display) 17 is incorporated, and a display screen of the LCD 17 is located at substantially the center of the display unit 12.

The display unit 12 is attached to the computer body 11 in such a manner that it is turnable between an open position and a close position. The computer body 11 has a thin, box-shaped chassis. A keyboard 13, a power button 14 for powering on/off the computer 10, an input operation panel 15, a touch pad 16, speakers 18A and 18B, and infrared receiver 20 are arranged on the top surface of the computer body 11.

The input operation panel 15 is an input device for inputting an event corresponding to a pressed button, and has a plurality of buttons for starting corresponding functions.

Next, a system configuration of the computer 10 will be described with reference to FIG. 2.

The computer 10 includes, as shown in FIG. 2, a CPU 101, a north bridge 102, a main memory 103, a south bridge 104, a GPU 105, a BIOS-ROM 109, a LAN controller 110, a hard disk drive (HDD) 111, an embedded controller/keyboard controller IC (EC/KBC) 116, and a keyboard (KB) 13, etc. The embedded controller/keyboard controller IC (EC/KBC) 116 has a ROM 116a and a RAM 116b. The firmware 30 is stored in the ROM 116a. Also, adjacent key maps and the like are stored in the RAM 116b.

The CPU 101 is a processor for controlling performance of the computer 10, and executes an operating system and keyboard applications or the like that are loaded from the hard disk drive (HDD) 111 into the main memory 103. The CPU 101 also executes a BIOS (Basic Input Output System) stored in the BIOS-ROM 109. The BIOS is a program for hardware control.

The north bridge 102 is a bridge device for connecting a local bus of the CPU 101 and the south bridge 104. The north bridge 102 contains a memory controller which access-controls the main memory 103. Also, the north bridge 102 has a function of executing communications with the GPU 105 via a PCI Express serial bus or the like.

The CPU 105 is a display controller for controlling the LCD 17 which is used as a display monitor for the computer 10. A display signal generated by the CPU 105 is transmitted to the LCD 17.

The south bridge 104 controls devices on an LPC (Low Pin Count) and devices on a PCI (Peripheral Component Interconnect). Furthermore, the south bridge 104 contains an IDE (Integrated Drive Electronics) controller for controlling the HDD 111.

The embedded controller/keyboard controller IC (EC/KBC) 116 is a one-chip microcomputer on which an embedded controller for power management, and a keyboard controller for controlling the keyboard (KB) 13 and the touch pad 16 are integrated. The embedded controller/keyboard controller IC (EC/KBC) 116 has a function of powering on and off the computer 10 in response to operation performed by a user using the power button 14. The above mentioned firmware 30 is stored in the ROM 116a of the EC/KBD 116, and a key map to be described later is stored in the RAM 116b.

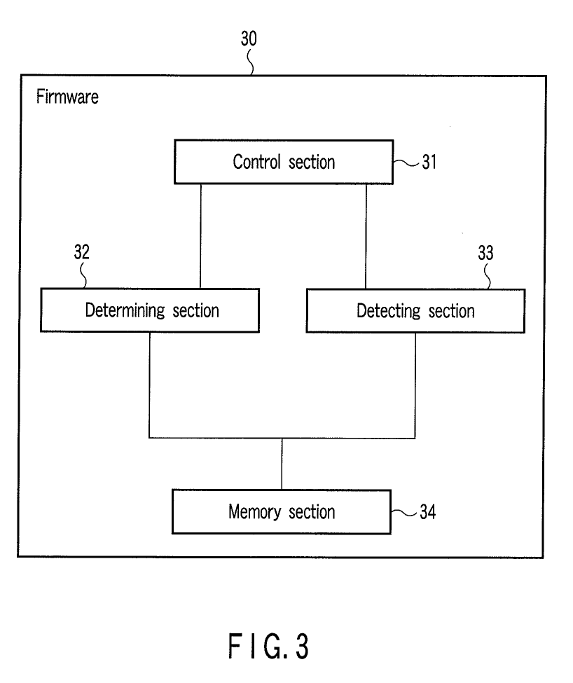

Next, FIG. 3 is a block diagram showing a functional configuration of a keyboard application according to the information processing device of the embodiment of the present invention.

The firmware 30 includes control section 31, determining section 32, detecting section 33, a memory section 34, etc. The control section 31 controls to cancel incorrect input on the basis of a pressed key. The detecting section 33 monitors a key press. The determining section 32 determines whether the key press satisfies predetermined conditions. The memory section 34 stores a pre-made correspondence table (table data) and the predetermined conditions, etc.

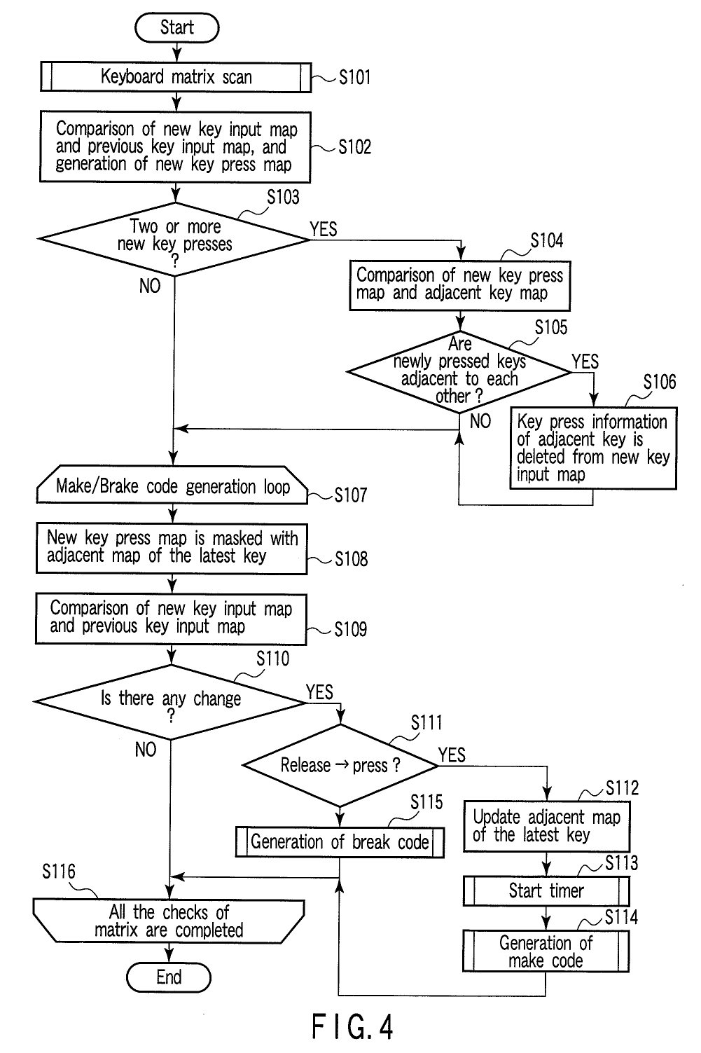

Next, a control method, to which the information processing device according to the embodiment of the present invention is applied, will be explained with reference to the flowchart shown in FIG. 4.

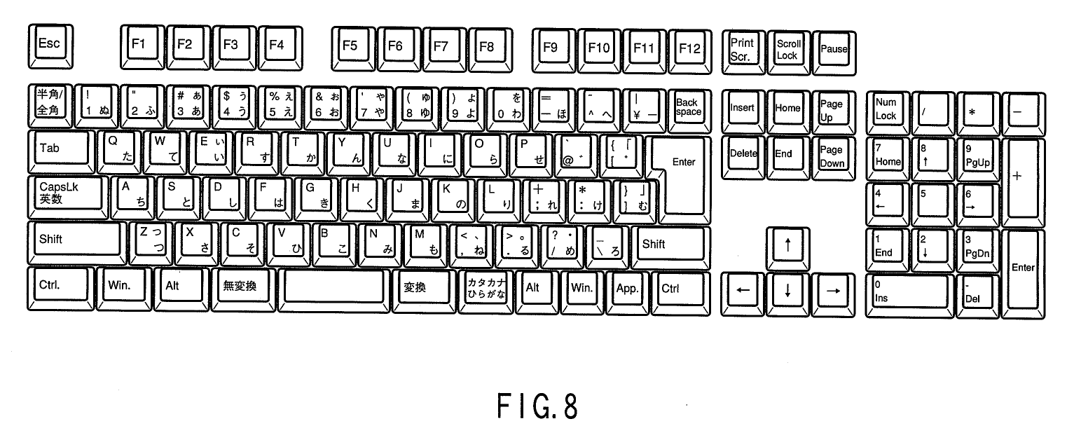

First, as shown in FIG. 6, “adjacent key maps” for respective keys in the keyboard is generated as table data. A typical keyboard is as shown in FIG. 8, and adjacent keys of “S” key, for example, are “A, W, Z, X, D, E”. Also, adjacent keys of “W” key, for example, are “Q, A, S, . . . ”. In this way, “adjacent key maps” for all of the keys are generated and stored in the memory section (RAM 116b) of the firmware 30. According to the present embodiment, when a key input is performed, determination of whether key inputs made within, for example, 50 ms after said key input are incorrect or not is executed. In addition, various predetermined conditions can be set. Incidentally, the shift key, control key, etc., which are generally called modifier keys, are not included in adjacent key maps, because those modifier keys are pressed in combination with other keys.

The detecting section 33 of the firmware 30 periodically executes a keyboard matrix scan for monitoring key inputs (key presses) (block S101).

When a key input is detected by the detecting section 33 of the firmware 30, a “new key input map” is generated on the basis of the input key. The “new key input map” is a key whose input into the computer 10 is fixed. Also, the “new key input map” and a “previous key input map” is compared. When “S” and “K”, for example, are determined to be newly input as a result of the comparison with the “previous key input map” of the key whose input is previously fixed, “S” and “K” are selected as candidates for “new key input maps”, and then “S” and “K” are generated as “new key press maps”. The “new key press maps” consist only of newly pressed keys, that is to say “S” and “K” (block S102). Incidentally, the “new key press maps” are candidates for “new key input maps”, and are key inputs whose inputs into the computer 10 are not yet fixed. Afterward, key inputs that are incorrect inputs are deleted and a “new key press map” is generated, and actual input is thereby executed.

Then, the determining section 32 of the firmware 30 determines whether there are two or more newly pressed keys (block S103). When the determining section 32 of the firmware 30 determines that there are two or more newly pressed keys (YES of block S103), “new key press maps” and “adjacent key maps” are compared (block S104). With this comparison, adjacent keys, which correspond to “S” and “K” being the “new key press maps”, are picked up as “adjacent maps of the latest keys” which are “A, W, E, D, Z, X” and “A, W, E, D, Z, X, J, I, O, L, M” (refer to FIG. 7). Incidentally, “K” is input 10 ms after the key input of “S”, and adjacent keys of keys that are pressed during 0-50 ms after the key input of “S” are picked up as “adjacent maps of the latest keys”. Also, the adjacent keys that have been picked up as “adjacent maps of the latest keys” for over 50 ms are sequentially cleared. For example, the “adjacent map of the latest key” corresponding to “S” is cleared when 50 ms has passed after “S” is input (refer to FIG. 7).

Subsequently, the determining section 32 of the firmware 30 determines whether or not “S” and “K”, which are both newly pressed keys, are adjacent keys (block S105). If “S” and “K” are not determined to be adjacent keys, a Make/Break code generation loop is started (block S107). Incidentally, the Make code is a code that is generated when a key press is recognized, and the Break code is a code that is generated when release of a key is recognized.

On the other hand, when the determining section 32 of the firmware 30 has determined that newly pressed keys are adjacent to each other in S105 (YES of S105), key press information of the adjacent keys are deleted from the “new key press maps” as incorrect input (block S106). For example, as shown in FIG. 7, when “A” is pressed 20 ms after the key input of “S”, a process for determining incorrect input is performed since “A” is pressed within 50 ms after the key input of “S” being the first key input. Since the pressed key “A” is applicable to the “adjacent map of the latest keys”, which is “A, W, E, D, Z, X, J, I, O, L, M”, the key press information of “A” is deleted from the “new key press maps” as incorrect input. Similarly, key press information of “J”, which is pressed 30 ms after the key input of “S”, is also deleted from the “new key press maps” since it is also applicable to the “adjacent map of the latest keys”.

When the Make/Break code generation loop is started in block S107, the determining section 32 of the firmware 30 masks the “new key press map” with the “adjacent map of the latest keys” (block S108). In other words, the two maps are compared, and key press information of the same key is then deleted from the “new key press map” as incorrect input. Subsequently, the determining section 32 of the firmware 30 compares the “new key input map” with the “previous key input map” (block S109). When the determining section 32 of the firmware 30 determines that there is a change in the maps as a result of the comparison performed in S109 (Yes of block S110), the determining section 32 determines whether a key is pressed or not (block S111). When, as a result of the determination 32 of the firmware 30, a key is determined to be pressed, in S111 (YES of block S110), the determining section 32 updates the “adjacent map of the latest key” (block S112). As shown in FIG. 7, when “A” is pressed, for example, the determining section 32 updates the “adjacent map of the latest key” (the “adjacent map of the latest key” updated based on the key press of “S” is cleared). Subsequently, control section 31 of the firmware 30 starts a timer (block S113). This timer is set, for example, to 50 ms. Then, the control section 31 of the firmware 30 generates a Make code (block S114), and finishes all the checking of the keyboard matrix (block S116).

On the other hand, when the determining section 32 of the firmware 30 determines that the key is released (No of block S111), a Break code is generated (block S115).

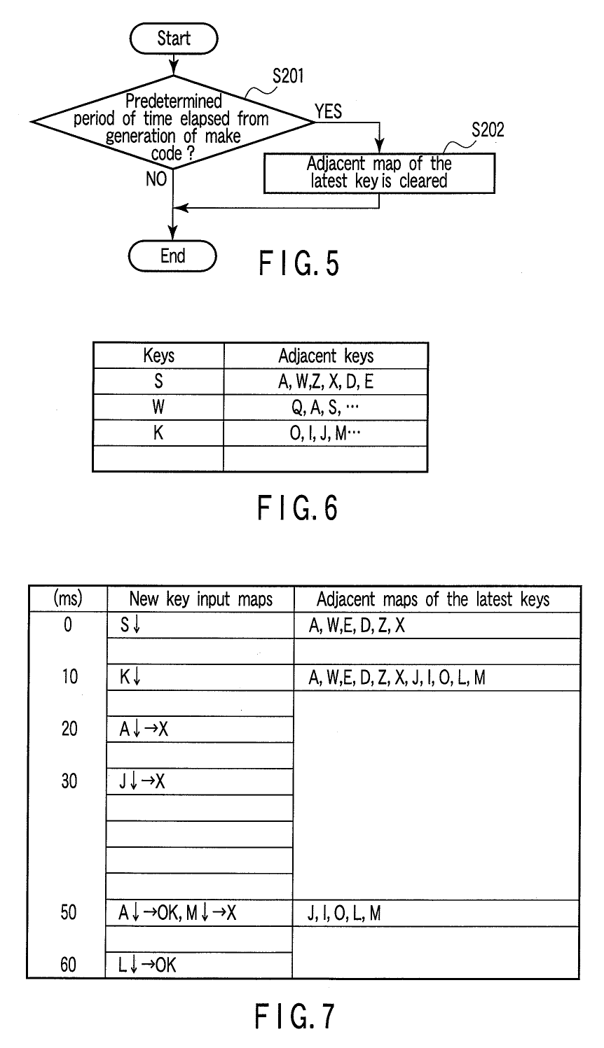

FIG. 5 is the flowchart indicating operation of the timer in S113. The determining section 32 of the firmware 30 determines whether a predetermined period of time has elapsed from the generation of a Make code (block S201). In the case where the determining section 32 of the firmware 30 determines that the predetermined period of time has elapsed from the generation of the Make code (YES of block S201), the “adjacent map of the latest key” is cleared (block S202). In the case where “A” is pressed at this time, an “adjacent map of the latest key” is “J, I, O, L, M”, and “A” is therefore not applicable. Thus, “A” is registered as a “new key input map”, a Make code is generated, and “A” is actually input to the computer 10. Also, when “M” is pressed, for example, an “adjacent map of the latest key” is (J, I, O, L, M) and “M” is applicable. “M” is therefore deleted from the “new key input map”.

After the deletion of “M”, as shown in FIG. 7, for example, when “L” is pressed 60 ms after the key input of “S”, “L” is not applicable because the “adjacent map of the latest key” is “J, I, O, L, M”. Therefore, the key input of “L” is registered as a “new key input map” and a Make code is generated, and the key input of “L” is thereby input to the computer 10.

It is possible to make the information processing device according to the above described embodiment have a learning function. That is to say, the information processing device learns an erroneous operation habit of a user when “release→press” of a key is detected at the same time, and a key scan method in which a priority order is obtained on the basis of the learned habit is used. More specifically, simultaneous key inputs, which are input within a predetermined period of time before an input of BackSpace, are recognized as an erroneous operation, and an input after the input of BackSpace is recognized as a correct input. In this way, combinations of simultaneous key inputs are weighed based on the occurrence frequency.

According to the present invention, when simultaneously detected key inputs are determined to be adjacent to each other, both key inputs are invalidated so that improvement in prevention of incorrect input can be achieved.

Note that the present invention is not limited to the above-described embodiments as are, and structural requirements can be modified and materialized within a range which does not deviate from a gist of the present invention at the practical phase. Further, various inventions can be formed by appropriately combining the plurality of structural requirements which have been disclosed in the above-described embodiments. For example, several structural requirements may be eliminated from all of the structural requirements shown in the embodiments. Moreover, structural requirements over different embodiments may be appropriately combined.

The present invention is made in consideration of the above described circumstances, and has an object to provide an information processing device capable of providing better prevention of incorrect input and a method of controlling the same.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information processing device comprising:
a keyboard arranged with a plurality of keys;
a detecting module configured to detect a key press of the keyboard;
a determining module configured to determine, when the detecting module detects two or more keys are pressed within a predetermined period of time, whether the two or more pressed keys satisfy predetermined conditions; and
an invalidating module configured to invalidate inputs made by pressing the two or more keys when the determining module determine that the two or more pressed keys satisfy the predetermined conditions respectively.

2. The information processing device of claim 1, wherein the predetermined conditions comprise that the two or more pressed keys are adjacent to each other.

3. The information processing device of claim 2, wherein the two or more pressed keys are not modifier keys.

4. The information processing device of claim 1, wherein the determining module is configured to learn a tendency of pressed key inputs and to reflect the tendency in the predetermined conditions.

5. The information processing device of claim 1, wherein the determining module is configured to make determination based on a pre-made correspondence table.

6. A control method used in an information processing device having a keyboard arranged with a plurality of keys, comprising;
determining, after detecting two or more keys are pressed in the keyboard within a predetermined period of time, whether the two or more pressed keys satisfy predetermined conditions, and
invalidating inputs made by both of the two or more pressed keys when it is determined that the two or more pressed keys satisfy the predetermined conditions respectively.

7. The control method of claim 6, wherein the predetermined conditions comprise that the two or more pressed keys are adjacent to each other.

8. The control method of claim 7, wherein the two or more pressed keys are not modifier keys.

9. The control method of claim 6, wherein the determining, further comprising;
learning a tendency of pressed key inputs and;
reflecting the tendency in the predetermined conditions.

10. The control method of claim 6, wherein the determination is performed based on a pre-made correspondence table.
